(19) United States
(12) Patent Application Publication
(10) Pub. No.: US 2008/0231290 A1
(43) Pub. Date: Sep. 25, 2008

(54) Capacitive Position Sensor

(75) Inventor: Victor Evgenievich Zhitomirsky, Cambridge (GB)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: SCIENTIFIC GENERICS LTD., Cambridge (GB)

(21) Appl. No.: 11/569,062

(22) PCT Filed: May 16, 2005
(86) PCT No.: PCT/GB05/01863

§ 371 Date: Jan. 29, 2008

(30) Foreign Application Priority Data
May 14, 2004 (GB) 0410845.2
Jun. 11, 2004 (GB) 0412978.9
Jun. 12, 2004 (GB) 0413182.7

(51) Int. Cl. G01R 27/26

(52) U.S. Cl. 324/661; 324/662

(57) ABSTRACT

A capacitive position sensor has a periodic array of electrodes which form capacitors between pairs of the electrodes. The location of a dielectric inhomogeneity in the vicinity of the sensor is determined by comparison of the relative change in the capacitance of the capacitors. The comparison may be carried out using a capacitive Wheatstone Bridge arrangement. The sensor configuration has the advantage that it is independent of the absolute value of the dielectric constant of the environment in which the sensor is located.

### FIELD OF THE INVENTION

The present invention relates to a capacitive position sensor and in particular to a capacitive position sensor that is useful in determining a liquid level.

### BACKGROUND OF THE INVENTION

Known capacitive liquid level sensors generally use two vertical spaced, for example coaxial, conductors to measure the change in capacitance between the conductors as the space between them fills with liquid. Such a sensor has the disadvantage that the capacitance of the conductors is not only dependent on the proportion of the space between them that is filled with liquid, but also to variations in the dielectric constant of the liquid. Consequently, if the composition of the liquid varies, which can be the case with automotive fuels for example, the liquid level sensor can become inaccurate.

Capacitive proximity sensors are also known that respond to a change in the capacitance of the sensor due to the presence of a dielectric object in the vicinity of the sensor. Again, such sensors are dependent on the dielectric constant of the object and can therefore lead to inaccuracies in level sensing applications.

### SUMMARY OF THE INVENTION

The present invention provides a capacitive position sensor comprising at least two first capacitors, which are mutually spaced along a measurement path. Each first capacitor is formed by spaced first and second electrodes such that the capacitance of the first capacitor is affected by changes in dielectric constant in the vicinity of the first capacitor. The capacitive position sensor further comprise an electrical circuit connected to both first capacitors and arranged to determine a change in the ratio of the capacitances of the first capacitors. The change in the ratio of the capacitances is indicative of the location along the measurement path of an inhomogeneity in the environment of the sensor.

Thus, according to the invention, the sensor determines a change in the ratio of the capacitances of the first capacitors, which means that the determination of the location along the measurement path of an inhomogeneity in the environment of the sensor can be made independent of absolute changes in the dielectric constant of the inhomogeneity. For example, in a simple embodiment for measuring liquid level, the two capacitors may be spaced along a vertical measurement path. When the liquid level passes the lowest capacitor, its capacitance changes relative to the higher capacitor and this indicates, independently of the dielectric constant of the liquid, the location of the liquid level between the two capacitors. More than two first capacitors may be provided to increase the resolution of the capacitive position sensor.

Conveniently, the electrical circuit may comprises a first parallel arm and a second parallel arm between supply connections for a common alternating drive voltage. One of the first capacitors may be connected in the first parallel arm and the other of the first capacitors may be connected in the second parallel arm. Each parallel arm may have a respective measurement point, such that a change in the potential difference between the measurement points of the first and second parallel arms indicates a change in the ratio of the capacitances of the respective first capacitors. In this case, the first capacitors may be incorporated in a capacitive “bridge” arrangement, which is a convenient configuration by which to determine changes in their relative capacitance.

The first and second parallel arms of the electrical circuit may be substantially electrically balanced, such that in the absence of an inhomogeneity in the environment of the sensor, there is substantially no potential difference between the measurement points. In this way, the potential difference between the measurement points may be used as an output signal indicative of a change in the ratio of the capacitances of the first capacitors.

The first capacitors may be substantially electrically identical. This allows the electrical circuit to be balanced more easily. However, this is not essential, as a balanced electrical circuit could also be achieved using electrically different first capacitors and compensating impedances.

Each parallel arm of the electrical circuit may comprises a respective second capacitor in series with the first capacitor and the measurement point of each parallel arm may be between the first and the second capacitor. In this arrangement, the first and second parallel arms can be arranged to form a conventional capacitive bridge.

The second capacitors may be arranged to be unaffected by environmental changes in dielectric constant, for example in order only to produce a convenient bridge geometry. However, in a presently preferred embodiment the capacitance of the second capacitor is affected by changes in dielectric constant in its vicinity. In this way, the second capacitors in the bridge can also be used as sensitive elements of the capacitive position sensor.

In a convenient arrangement, the second capacitor of each parallel arm is formed by the second electrode of the first capacitor and a third electrode. In this way, the first and second capacitors are formed in series with the second electrode providing the electrical connection between them and a plate of each capacitor. The second electrode may be directly electrically connected to the measurement point of the respective parallel arm. In this cases, the potential difference between the measurement points of the first and second parallel arms of the electrical circuit is the potential difference between the second electrodes of the respective arms.

Desirably, the second capacitors are substantially electrically identical, in order to more easily achieve a balanced capacitive bridge. Furthermore, the second capacitors may be substantially electrically identical to the first capacitors. In this way, a balanced capacitive bridge may be achieved simply by virtue of the electrical configuration of the first and second capacitors (in the absence of an environmental inhomogeneity).

As mentioned above, the range and/or the resolution of the position sensor may be increased by additional first capacitors. In one embodiment, the electrical circuit comprises a plurality of said first parallel arms and a corresponding plurality of said second parallel arms, each first and second parallel arm having at least a respective first capacitor. Thus, additional first capacitors may be added to the sensor by adding pairs of first and second parallel arms. Pairs of parallel arms are preferable in that they can maintain the balance of the bridge.

Where the sensor comprises a plurality of first and/or second capacitors, the electrodes of each capacitor may vary in size with position on the measurement path, such that the capacitance of the first (or second) capacitor with a constant local dielectric constant provides an indication of the position of the capacitor on the measurement path. For example, the surface area of the electrode may increase with position along the measurement path. Preferably, the increase in size is proportional to position along the measurement path. In this way, magnitude of the capacitance of each first (or second) capacitor encodes position along the measurement path.

In one embodiment, the capacitive position sensor comprises a first capacitive position sensor comprising a plurality of first (or second) capacitors distributed along the measurement path and a second capacitive position sensor comprising a corresponding plurality of first (or second) capacitors distributed along the same measurement path, wherein the surface area of the electrodes forming the first (or second) capacitors of the first capacitive position sensor increases with position along the measurement path and the surface area of the electrodes forming the first (or second) capacitors of the second capacitive position sensor decreases with position along the measurement path, such that each first capacitor from the first capacitive position sensor is paired with a first capacitor from the second capacitive position sensor at the same position along the measurement path and the sum of the capacitances of the paired first capacitances is equal for all such pairs of first capacitors in the capacitive position sensor in the absence of an inhomogeneity in the environment of the sensor. In this way, a ratiometric comparison of the signal(s) from the first capacitive position sensor and the signal(s) from the second capacitive position sensor can be used to determine the position of an inhomogeneity along the measurement path independently of the absolute dielectric constant of the inhomogeneity.

Where the electrical circuit includes a plurality of first and second parallel arms, the measurement points of the first parallel arms may be electrically connected to form a common measurement point. Similarly, the measurement points of the second parallel arms may be electrically connected to form a common measurement point. In this case, the signal between the respective common measurement points for a bridge which is balanced in the absence of an inhomogeneity is indicative of a change in the relative capacitance of any pair of first capacitors from respective first and second parallel arms.

Furthermore, the total capacitance of the capacitors in each of the parallel arms can be determined. For example, the total capacitance may be measured between a connection for the alternating drive voltage and the common measurement point for the parallel arm. The total capacitance of the parallel arm may provide an indication of the extent of the inhomogeneity in the environment of the sensor. For example, in the case of a liquid level sensor, the total capacitance may indicate the number of first and/or second capacitors that are below the liquid level.

In general, the change in total capacitance between at least two electrodes of the sensor may be used to provide an estimate of the position of an inhomogeneity along the measurement path. The exact position of the inhomogeneity may be determined by a comparison of the change in capacitance of the first and/or second capacitors.

The sensor may comprise a plurality of first capacitors distributed as a regular periodic array along the measurement path. This is desirable in that the response of the sensor to an inhomogeneity passing along the measurement path will be periodic. The periodicity of the response can be used to determine the location of an inhomogeneity along the measurement path, for example within a period of the array. The location of the inhomogeneity may be determined further by a measurement of total capacitance as previously described.

The first capacitors of the first parallel arm(s) may alternate in the periodic array with the first capacitors of the second parallel arm(s). In this way, the location of an inhomogeneity within a period of the array may be determined by the unbalancing of the bridge.

The sensor may comprise a plurality of second capacitors distributed as a regular periodic array along the measurement path, with one second capacitor in the space between each pair of successive first capacitors. Such an arrangement provides increased resolution of the position of an inhomogeneity within a period of the array. The second capacitors of the first parallel arm(s) may alternate in the periodic array with the second capacitors of the second parallel arm(s).

The electrical circuit may comprise a switching arrangement configured to disconnect the alternating drive voltage from the supply connections of the first and second arms and to apply the alternating drive voltage between the respective measurement points of the first and second parallel arms, whereby a potential difference measured between the respective supply connections of the first and second parallel arms is indicative of the ratio of the capacitances of the respective first capacitors of the first and second parallel arms. In other words, the electrical circuit may be arranged to interchange the measurement points and the supply connections so that the measurement points are used as supply connections and the supply connections are used as measurement points. When the connections are switched in this way, the first capacitors of the first parallel arm are in series with the first (or second) capacitors of the second parallel arm with a measurement point (previously the supply connection) between them and vice versa. This allows a measurement to be taken which is effectively shifted along the measurement path by the distance between the corresponding capacitors of the each parallel arm. By comparing the shifted signal to the unshifted signal, improved accuracy and reliability can be achieved.

As mentioned above, the sensor may comprise a periodic array of first and second capacitors. The first capacitors may be formed between a first electrode and a second electrode. The second capacitors may be formed between a third electrode and a fourth electrode. Conveniently, the first electrode may form a continuous electrode which follows generally the measurement path and is common to all first capacitors. Similarly, the fourth electrode may form a continuous electrode which follows generally the measurement path and is common to all first capacitors. Thus, where the measurement path is linear, the first and/or fourth electrodes may form continuous linear electrodes. The continuous first and fourth electrodes may be physically parallel along their length.

The second and third electrodes may be connected in a series chain of alternating second and third electrodes connected to the measurement point of the respective parallel arm. The second electrodes connected to the same measurement point may be displaced along the measurement path relative to the third electrodes connected to that measurement point, with one such third electrode in the space between each pair of such successive second electrodes. The second electrodes connected to the same measurement point may be displaced in a direction perpendicular to the measurement path relative to the third electrodes connected to that measurement point, such that the second electrodes are closer to the first electrode(s) and the third electrodes are closer to the fourth electrode(s).

The second electrodes connected to a first common measurement point may be arranged between the third electrodes connected to a second common measurement point and the first electrode(s) and at the same position along the measurement path as the third electrodes connected to the second common measurement point. Similarly, the third electrodes connected to a first common measurement point may be arranged between the second electrodes connected to a second common measurement point and the fourth electrode(s) and at the same position along the measurement path as the second electrodes connected to the second common measurement point. In this way, for example, two chains of second and third electrodes connected to different measuring points may be intertwined between linear first and fourth electrodes. This has the advantage that the first capacitors connected to one common measurement point are located at the same position along the measurement path as the second capacitors connected to the other common measurement point so that they will be similarly affected by changes in dielectric constant at that position.

The electrical circuit may comprise a first set of first and second parallel arms and a second set of first and second parallel arms, each set of first parallel arms having a respective common measuring point and respective first, and preferably second, capacitors and each set of second parallel arms having a respective common measuring point and respective first, and preferably second, capacitors. The first, and preferably second, capacitors of each set of parallel arms preferably form a periodic array along the measurement path with the same period for each set. The periodic array of capacitors of the first set of parallel arms is preferably shifted by an offset in the measurement direction relative to the periodic array of capacitors of the second set of parallel arms. The offset is preferably less than one half period of the array and preferably a quarter period. When the offset is a quarter period, the response of one set of parallel arms will be sine-like and the response of the other set of parallel arms will be cosine-like. This allows a ratiometric determination of the position of the inhomogeneity, because it is not possible for both signals to be zero at the same time.

This in itself is believed to be a novel aspect of the invention and thus viewed from a further aspect, the invention provides a capacitive position sensor comprising a first periodic array of capacitors distributed along a measurement path and a second periodic array of capacitors distributed along a measurement path, wherein the period of the first and second arrays is equal and the first array is offset in the measurement direction from the second array by a non-zero offset of less than one half period.

The capacitive position sensor may be used as a liquid level sensor. In this case, the inhomogeneity in the environment of the sensor may be an interface between a liquid and a gas, between a two liquids of different dielectric constant, between a liquid and a solid phase (such as a particulate material), between a solid phase and a gas or between conductive and non-conductive materials.

Alternatively, the capacitive position sensor may be arranged to identify the position of an inhomogeneity on the surface of an otherwise homogeneous surface, for example of a conductive material. Such a surface may be flat or curved. The inhomogeneity may be of conductive material, such as a deformation of a conductive surface. Alternatively, the inhomogeneity may be of non-conductive (dielectric) material on a conductive surface.

The electrical circuit may comprise an AC generator to produce the alternating drive voltage. The generator may generate a drive voltage in the form of a periodic sine wave. The electrical circuit may further comprise a synchronous detector synchronised to the alternating drive voltage.

Alternatively, the electrical circuit may comprise a pulse generator to produce the alternating drive voltage. The pulse generator should have a duty cycle ratio greater than one so that the pulses are spaced by a time period large than their width. The electrical circuit may further comprises switches, for example solid state switches, configured to connect and disconnect reference capacitors between the measurement points of the parallel arms in synchronous with the pulses of the alternating drive voltage. The electrical circuit may further comprise low frequency signal amplifiers to amplify the signals on the reference capacitors and process the signals in the low frequency domain.

The electrodes of the sensor may be formed on a substrate of printed circuit board material, for example by photolithography. Alternatively, the electrodes may be formed by conductive ink, for example on a moulded plastics substrate. A physical gap may be formed in the substrate between the electrodes to prevent the formation of a parasitic film of liquid between the electrodes when they are not submerged in the liquid.

### BRIEF DESCRIPTION OF THE DRAWINGS

Embodiments of the invention will now be described by way of example only and with reference to the accompanying drawings, in which:

FIG. 1 is a schematic representation of a first embodiment of a liquid level sensor according to the invention;

FIG. 2A is a schematic representation of a second embodiment of a liquid level sensor according to the invention;

FIG. 2B is a schematic representation of a third embodiment of a liquid level sensor according to the invention;

FIG. 3 is a circuit diagram representing the liquid level sensor of FIG. 1;

FIG. 4A is a schematic representation of a fourth embodiment of a liquid level sensor according to the invention;

FIG. 4B is a further representation of the liquid level sensor FIG. 4A;

FIG. 5 is a circuit diagram representing the liquid level sensor of FIGS. 4A and 4B;

FIGS. 6A to 6F illustrate the operation of the liquid level sensor of FIGS. 4A and 4B;

FIG. 7 is a schematic representation of a fifth embodiment of a liquid level sensor according to the invention;

FIG. 8 illustrates the operation of the liquid level sensor of FIG. 7;

FIGS. 9A to 9C are a schematic representation of a first embodiment of an inhomogeneity detector according to the invention;

FIG. 10 is a circuit diagram representing the inhomogeneity detector of FIGS. 9A to 9C;

FIGS. 11A to 11C are a schematic representation of a second embodiment of an inhomogeneity detector according to the invention;

FIG. 12 is a circuit diagram representing the inhomogeneity detector of FIGS. 9A to 9C;

FIG. 13 illustrates an algorithm for determining a liquid level with a liquid level sensor according to the invention;

FIG. 14A is a schematic diagram of a processing circuit for the output of the liquid level sensor of FIG. 2A;

FIG. 14B is a schematic diagram of an alternative processing circuit for the output of the liquid level sensor of FIG. 2A; and

FIG. 15 is a schematic diagram of a further alternative processing circuit for the output of the liquid level sensor of FIG. 2A.

FIG. 16 is a schematic diagram of a processing circuit for the ratiometric algorithm of FIG. 15 and FIG. 14A.

### DETAILED DESCRIPTION OF EMBODIMENTS

Embodiments of the invention enable detection of the spatial position of an inhomogeneity in the dielectric constant (permittivity) in the space around a sensor. The sensor may be arranged as an array of pixels along a straight line or any curved line. In general, this line is the measurement path. The sensor can detect the position of the interface between a liquid (or flowable materials like grain or powder) and the air, the position and displacement of a single dielectric or metallic object adjacent to the sensor, movement of an air bubble inside a liquid (e.g. in a level gauge), etc. The sensor may be placed externally near the dielectric (plastic or glass) walls or internally inside the container (e.g. in a fuel tank) but at the distance of at least a few centimetres from the metallic walls.

The measurement set-up of the sensor is based on detecting changes of the mutual capacitance between adjacent pixels in the array of pixels. This change is caused by the change of the value of permittivity in the space near the sensor head. A self-reference approach adopted for the array of pixels allows, for instance, using a sensor without pre-calibration for measuring levels of different liquids regardless of the variation of the permittivity between different liquids.

A major development is the provision of a self-compensating multiple period array of pixels which are wired to form a single balanced bridge. If the space around the sensor head is homogenous, the balanced bridge will provide a nearly zero output. The presence of an inhomogeneity will unbalance the bridge so that a non-zero voltage will appear at the bridge output. Two types of output—a sine-like and a cosine-like relative to the position of “the centre of gravity” of the inhomogeneity along the sensor head—are enabled by the inherent geometry of the pixel array. This enables a very accurate measurement of the displacement of “the centre of gravity” of the inhomogeneity of the permittivity in the space around the sensor head. The accuracy of such measurements approaches one part per few hundreds of the range of the sensor and is not largely affected by the nature of the inhomogeneity itself.

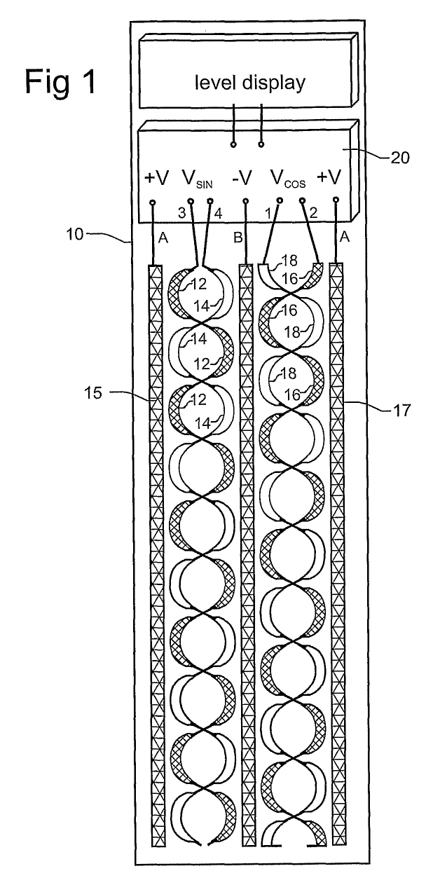

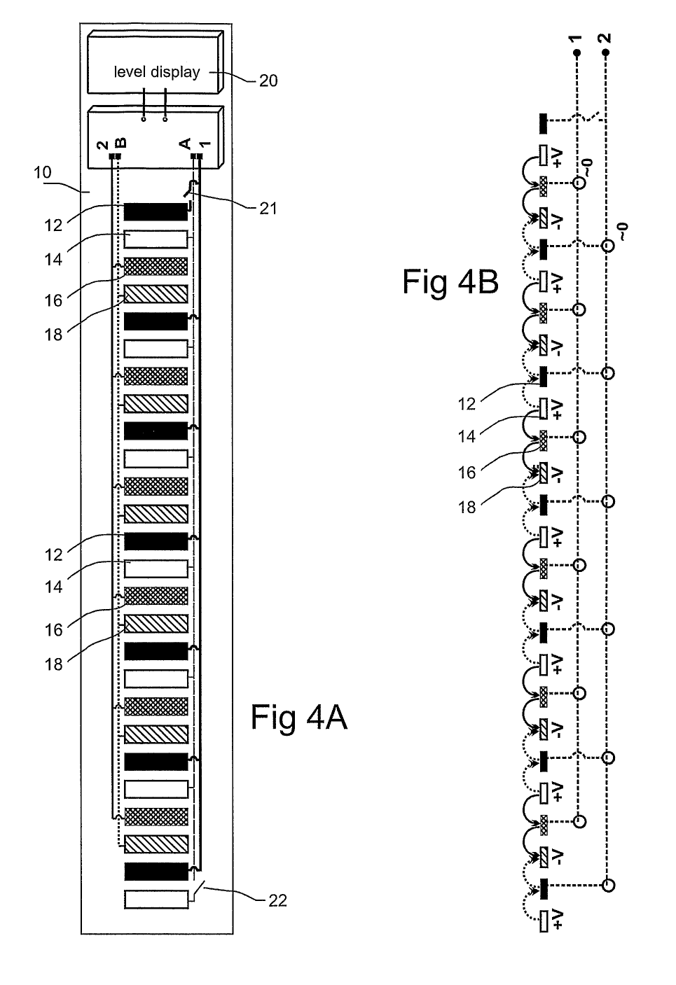

A capacitive sensor bridge arrangement can be based on an array of electrodes organised along one direction as shown in FIG. 4A or as a more complex distribution of electrodes organised both along the predetermined direction and perpendicular to this direction. One particular embodiment of this arrangement is shown in FIG. 1. Here two pairs of electrodes 12, 14 and 16, 18 are organised in a periodic pattern along the length of the sensor head 10.

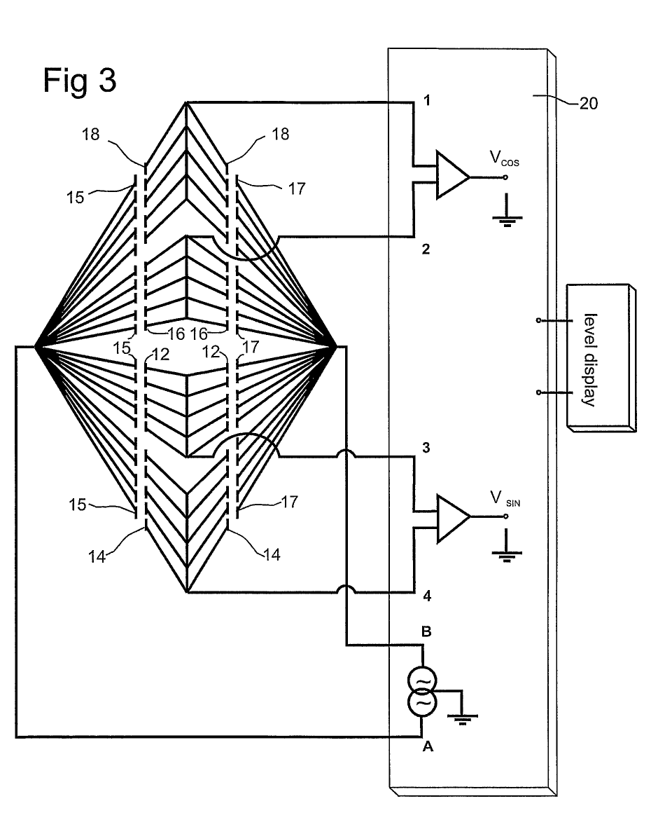

The equivalent scheme of the electrodes 12, 14, 16, 18 shown in FIG. 1 is further described in FIG. 3. Three vertical electrodes 15, 17 shown in FIG. 1 in the form of continuous stripes are used to provide a symmetrical voltage excitation for the measurement set-up. Two sets of periodic electrodes 12, 14, 16, 18 are organised to pick-up a voltage induced by the liquid around the sensor head 10. If the level of liquid moves along the length of the sensor head 10 the differential signals in both the periodic electrode pairs changes in a periodic manner.

The differential voltage between pairs of electrodes 1-2 (16, 18) and 3-4 (12, 14) in the case shown in FIG. 1 will be equal to zero in a homogeneous environment regardless of the accuracy of the balance of the symmetrical excitation voltage. The balanced drive is used to reduce a value of common mode voltage on these electrodes.

The pattern of the two periodic pairs 12, 14 and 16, 18 of electrodes is physically shifted by a quarter of the period along the length of the sensor head 10. This allows the application of a ratiometric technique to detect the exact position of an inhomogeneity along the length of the sensor head 10. For instance, if a differential signal induced by the presence of a liquid interface varies in a sinusoidal-like manner with the position of the liquid interface along the length of the sensor head 10, the two pairs of the periodically varying electrodes 1-2 (16, 18) and 3-4 (12, 14) in FIG. 1 will form sine-like and cosine-like measurement channels Vₛᵢₙ and V_{cos}. The exact position of the liquid interface can then be calculated as the arctangent of the ratio of voltages measured between each pair of electrodes.

However, the design of the electrodes 12, 14, 16, 18 shown in FIG. 1 will allow for an accurate ratiometric algorithm only if the interface between the liquid and the gas is aligned perpendicularly to the length of the sensor head 10. If the liquid interface is inclined, then the two pairs of electrodes shown as sin-like and cosine-like in FIG. 1 may measure dissimilar positions of the liquid interface at different spatial points. Thus, the ratiometric algorithm may fail to provide an accurate measurement of the position of the liquid interface.

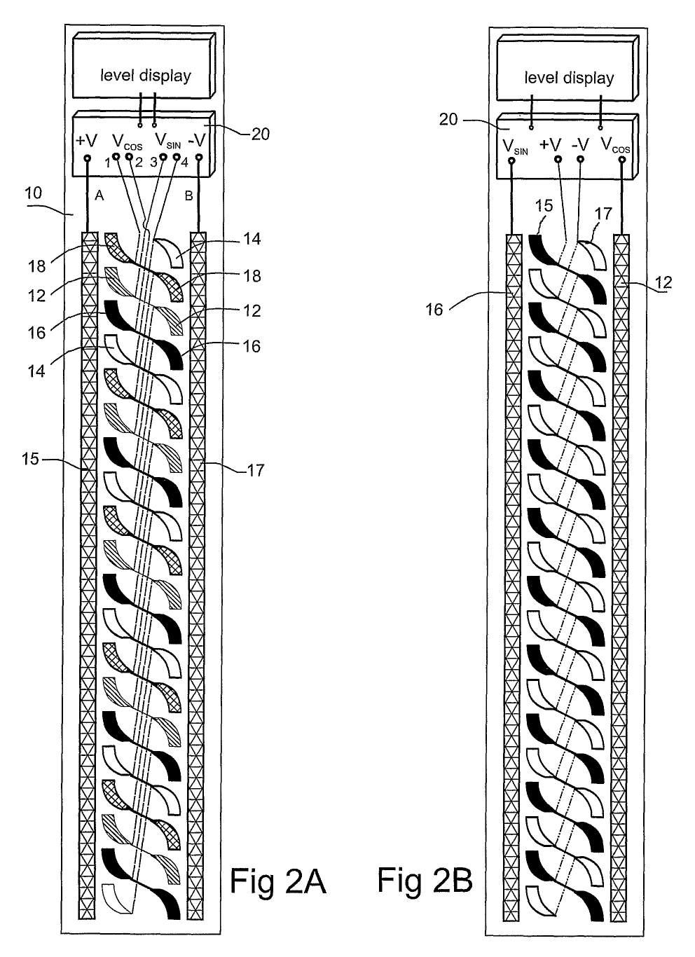

The problem of working with an inclined liquid interface is further resolved with a design of electrodes shown in FIG. 2A. The pattern of inner electrodes 12, 14, 16, 18 consists of repeatable shapes connected in a periodic array with four dissimilar groups of electrodes as further shown in FIG. 2A. The difference of the voltages between two pairs 1-2 (16,18) and 3-4 (12,14) of FIG. 2A will provide a sine-like and cosine-like induced signals in the same manner as described above for electrodes 1-2 (16,18) and 3-4 (12,14) of FIG. 1. The equivalent electronic scheme for the electrodes shown in FIG. 2A will remain the same as for the electrodes shown in FIG. 1 and is further shown in FIG. 3.

The different arrangement of electrodes in FIG. 2A will cause the signal in both pairs of electrodes 1-2 (16, 18) and 3-4 (12, 14) of FIG. 2A to be determined simultaneously by the position of the liquid interface at the left excitation line A (15) of FIG. 2A and right excitation line B (17) of FIG. 2A. For a sine-like form of the induced signal between the pairs of electrodes 1-2 (16, 18) or 3-4 (12, 14) the inclination of the interface between the liquid and the gas will not disturb the phase of the measured sine-like signal but will rather change the amplitude of the induced signal in both measurement channels.

From the design of electrodes shown in FIG. 2A it is clear that the measurement electrode pairs 1-2 (16, 18) and 3-4 (12, 14) form periodic patterns which are shifted one from the other by a quarter of the period. Thus for sine-like behaviour of the induced signal against the liquid interface position along the length of the sensor head 10 signals in channels 1-2 and 3-4 can be treated as a cosine-like and sine-like signal respectively. A ratiometric algorithm can be used to calculate the exact position of the liquid interface. For instance, the arctangent of the ratio of voltages measured in both channels simultaneously can be used to detect the position of the liquid interface inside a single period.

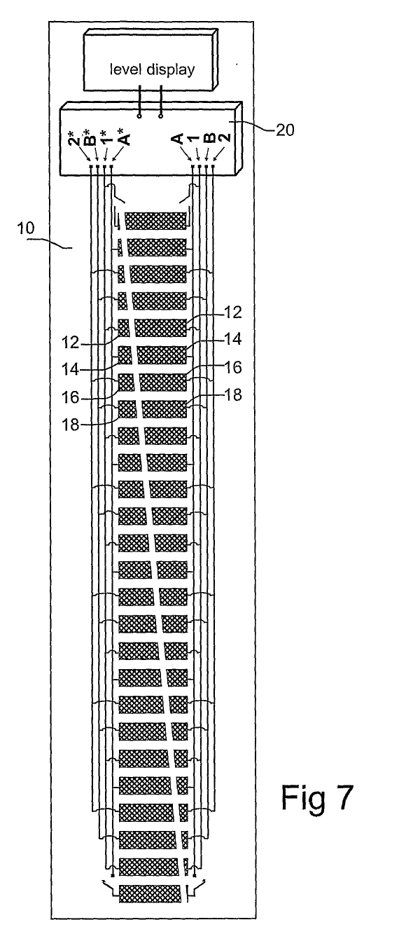

In order to decrease the sensitivity of the measurement set-up to films of liquid formed due to the oscillation of the liquid interface in the measurement volume, through grooves can be formed between the measurement electrodes 12, 14, 16, 18 and the excitation electrodes 15 and 17 of FIG. 2A. The actual physical gap will prevent formation of thick films of the liquid at the edges of the excitation electrodes 15 and 17 and thus will allow for more robust measurements. The same physical grooves between adjacent electrodes can be used for all other embodiments including the electrodes shown in FIG. 4A and FIG. 7.

The electrodes shown in FIG. 2A are organised in the same plane. Such a design allows for more reliable and reproducible manufacturing of the sensor head 10. However other arrangements of the electrodes are possible. For instance, excitation electrodes A (15) and B (17) can be placed out of the plane created by electrodes 12, 14, 16, 18. For instance, both electrodes A (15) and B (17) can be placed parallel to each other behind electrodes 12, 14, 16, 18 at a fixed distance of about several millimetres from the plane formed by electrodes 12, 14, 16, 18. The shape of the electrodes 12, 14, 16, 18 is changed for this embodiment so that the surface area of each electrode 12, 14, 16, 18 varies in the sine-like or another smooth manner along the length of the sensor head 10.

In order to measure the exact position of the liquid interface a relatively simple ratiometric algorithm can be used for signals measured in channels 1-2 (16,18) and 3-4 (12,14) of the electrode design shown in FIG. 2A. The exact position of the liquid interface determined by such an algorithm is ambiguous, as for the periodic electrode pattern one needs to further determine the number of periods completely covered by the liquid.

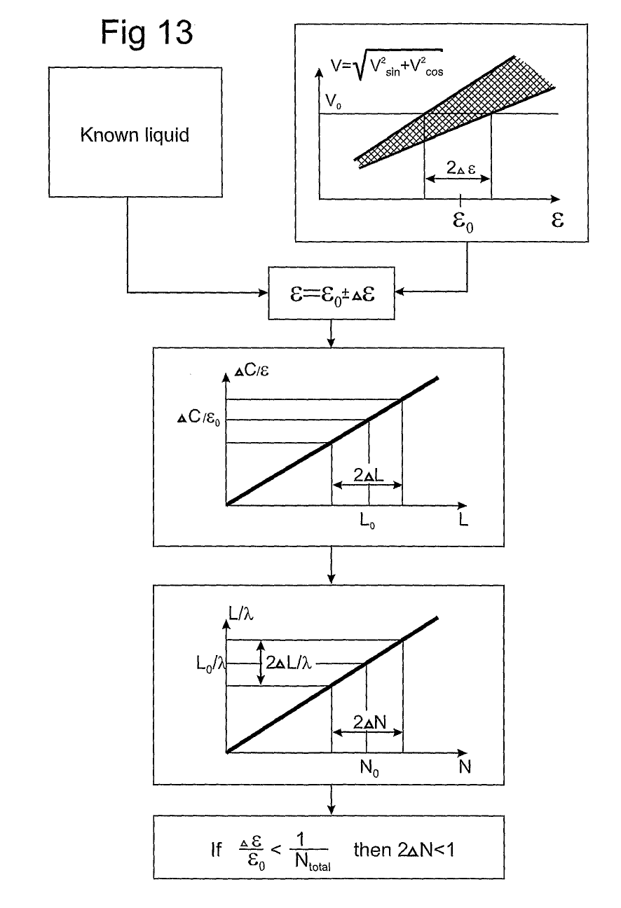

This can be achieved by measuring the change of the value of the capacitance between pairs of electrodes A-B (15, 17) or 1-2 (16, 18) or 3-4 (12, 14). If the dielectric constant of the liquid to be measured is known to some accuracy, the calibration curve of the dependence ΔC can be used to determine roughly the length of the sensor head 10 covered by the liquid. The algorithm for doing this is further shown in FIG. 13. As described by FIG. 13 the uncertainty Δε in the value of the dielectric constant will introduce an uncertainty in the length of the sensor head covered by the liquid. However, as long as the relative uncertainty of the value of the dielectric constant does not exceed the reciprocal of the number of periods Nₜₒₜₐₗ along the length of the sensor head, the algorithm will allow the determination of the rough position of the liquid interface inside the defined period of the periodic pattern.

Even further calibration of the measurement set-up is achievable by calculating the total amplitude of the measured signal in the sine-like and cosine-like channels. The square root of the sum of the squares of voltages measured instantaneously in both channels 1-2 (16,18) and 3-4 (12,14) of FIG. 2A will be in a first approximation a function of the dielectric constant of the liquid in the system. This dielectric constant might vary with temperature or can be further affected by additives in the liquid. The calibration curve using the amplitude of induced signals will allow calibration for such changes in the dielectric constant thus achieving better accuracy for determining the length of the sensor head covered with a liquid.

However, variations of the angle of the liquid interface to the normal direction to the length of the sensor head can significantly reduce the value of the amplitude of the measured signal. The amplitudes of the measured signals will be affected simultaneously for sine-like and cosine-like channels 1-2 (16,18) and 3-4 (12,14) of FIG. 2A. Thus it will not prevent the use of ratiometric algorithm but may create significant uncertainty for extracting the corrected value of the dielectric constant from the measured amplitudes.

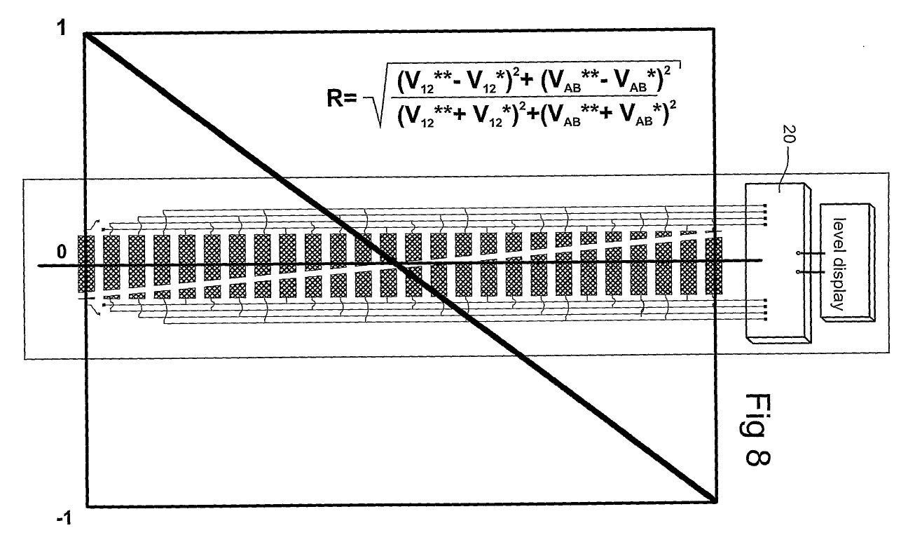

An alternative approach can be used in the case when the dielectric constant of the liquid to be measured is not known to the degree which is necessary to determine the position of the liquid to a period of the pattern. This alternative arrangement is shown in FIG. 4, FIG. 7, and FIG. 8 and described in more detail below. The amplitudes of the signals in the sine-like and cosine-like channels of the sensor in FIG. 7 are also affected by the inclination of the liquid interface. However further encoding of the surface area of electrodes along the length of the sensor head allows for rough determination of the liquid interface for an unknown liquid. The accuracy of the ratiometric set-up shown in FIG. 8 allows for determining the position of the liquid interface with accuracy better than the width of the sensor array even for large angles between the liquid interface and the normal to the length of the sensor head. Thus, such an approach has an advantage for measuring liquid level of liquids with dielectric constants varying in a large range, and for situations when the liquid interface may oscillate around the horizontal line over a large range of angles.

Another way of resolving the ambiguity of the ratiometric algorithm is particularly simple. A single period arrangement for electrodes 12, 14, 16, 18 can be used for the embodiment shown in FIG. 2A. A single period embodiment with sine-like and cosine-like dependencies in the measurement channels 1-2 (16,18) and 3-4 (12,14) allows unambiguous determination of the liquid level position. Another variation of the design of the electrodes shown in the FIG. 2A involves a similar but quasi-periodic arrangement for the electrodes 12, 14, 16, 18. The quasi-periodic arrangement is used to create a cosine-like and sine-like response in the measurement channels 1-2 (16,18) and 3-4 (12,14) but with a single period for cosine and sine functions against the position of the liquid level interface along the length of the sensor head 10. A single period like dependence in the measurement channels 1-2 (16,18) and 3-4 (12,14) can be achieved in spite of the multiple quasi-periodic arrangement for electrodes 12, 14, 16, 18. For this purpose a continuous variation of the parameters of the electrodes 12, 14, 16, 18 is introduced from period to period. Such variation can include variation of the surface area of electrodes 12, 14, 16, 18 and/or variation of the gap between electrodes 12, 14, 16, 18 and electrodes 15 and 17 from one period to another period.

The determination of the liquid level with a ratiometric algorithm is performed unambiguously for the whole range of liquid level interface positions along the length of the sensor head 10 if measurement channels 1-2 (16,18) and 3-4 (12,14) reconstruct a single period function, such as a single period sine-like and cosine-like dependences against position of the liquid level interface along the length of the sensor head 10. The signals in the measurement channels 1-2 (16,18) and 3-4 (12,14) can also be organised as another smooth and dissimilar functions of the liquid level position along the sensor head 10. A calibrated ratiometric function can be used to calculate unambiguously the position of the liquid interface along the length of the sensor head 10. For instance, signals in channels 1-2 (16,18) and 3-4 (12,14) might have a wide range of quasi-linear behaviour against the position of the liquid level interface. In such a case, a ratiometric function like R=(V₁₋₂−V₃₋₄)/(V₁₋₂+V₃₋₄) can be used to calculate the exact position of the liquid interface along the length of the sensor head 10.

FIG. 2B shows an alternative design of the sensor head 10. The excitation and detection electrodes 15 and 17 are exchanging their roles compared to the wiring of the electrodes shown in FIG. 2A. The arrangement of electrodes of FIG. 2B has the same inherent problem as the electrode design of FIG. 1. Measurements on sine-like (16) and cosine-like (12) channels are performed at two dissimilar points in space. Thus for an inclined liquid interface it may not be possible to use a ratiometric technique to extract the exact location of the liquid interface.

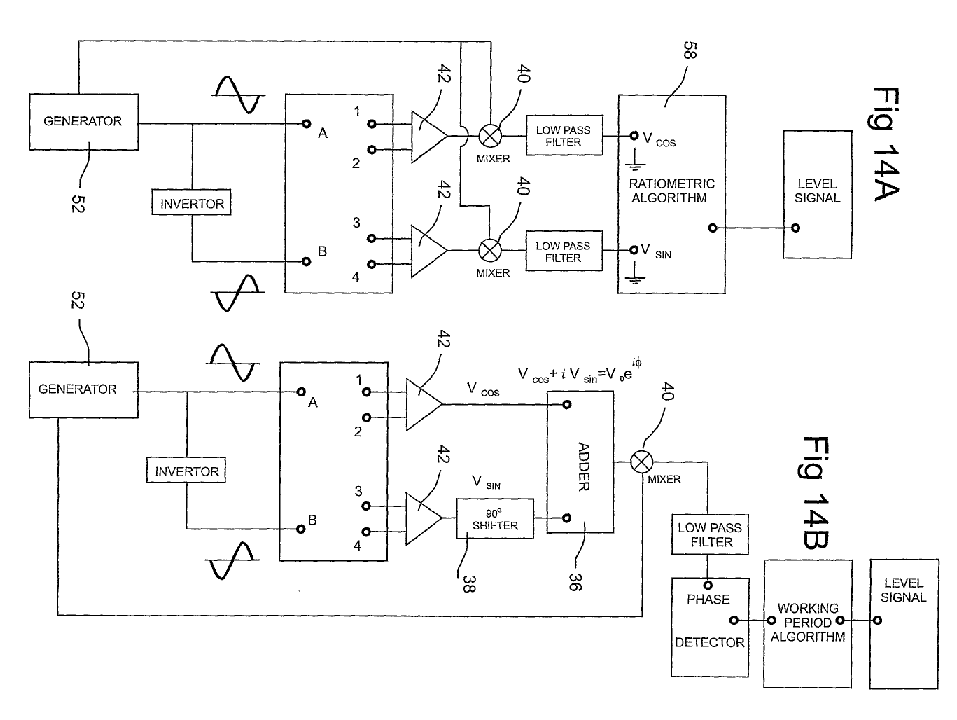

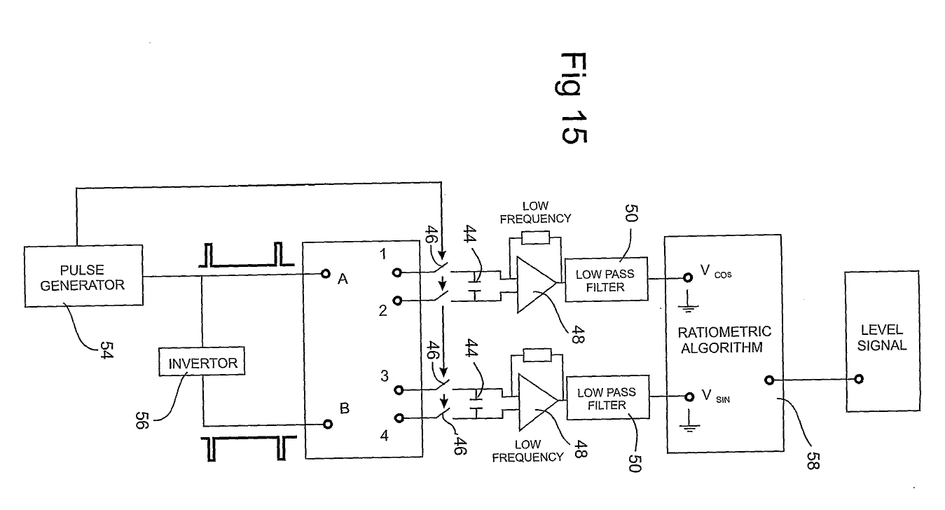

FIG. 14A, FIG. 14B and FIG. 15 describe further aspects of the electronics used for measurements with the electrode arrangement shown in FIG. 2A. A variety of options are known in the prior art for arranging such measurements.

The most straightforward solution of FIG. 14A involves AC generator 52 for excitation and synchronous measurement of signals 1-2 and 3-4 after differential amplifiers 42 with the help of mixers 40. The mixers 40 will down convert an AC signal. The component of the AC signal in phase with the excitation voltage from the generator 52 will be down converted into a DC signal. Low pass filtering is used after the mixing to remove parasitic high frequency components of the signal which are mainly due to picked-up noise. A ratiometric algorithm organised through using cosine-like and sine-like voltages will allow the calculation of the exact position of the liquid interface from the DC-like signals slowly varying in time reflecting the movement of the liquid level.

A slightly different version is shown in FIG. 14B. To simplify the ratiometric algorithm, the signal from one of the channels is shifted by 90 degrees by a phase shifter 38. After a summator 36 the signal from the sine-like and cosine-like channels will become equal to V=V_{cos}+i*Vₛᵢₙ=V₀e^{iφ} where phase φ is equal to atan(Vₛᵢₙ/V_{cos}). Thus by implementing phase sensitive mixing with the signal from the generator 52 and measuring the phase of the original AC signal it is possible to determine the exact position of the liquid interface inside the unit period of the pattern of FIG. 2A.

The capacitive sensors can operate at a range of frequencies. However for the electrode design shown in FIG. 2A mutual capacitances are rather small and so the impedance of the capacitive arms of the bridge shown in FIG. 3 will be relatively large. It is preferable to operate at frequencies above 1 MHz or even 10 MHz in order to decrease the value of the impedance associated with mutual capacitances. Very high values for impedances will make it difficult to balance the bridge in the presence of parasitic resistive coupling to the environment. Increasing the frequency of the AC excitation is not the most preferable option. The cost of electronics and especially the cost of signal amplifiers strongly increases with the frequency.

Instead of AC excitation it is possible to use pulsed excitation 54 with short pulses and a large duty cycle. The electronic scheme for such a measurement set-up is shown in FIG. 15. Pulsed excitation can be created using fast solid state switches. The same type of solid state switches 46 can be used to connect and disconnect reference capacitors 44 shown in FIG. 15 from the electrode channels 1-2 and 3-4. As a result, the voltage accumulated on the reference capacitors 44 will vary slowly over time reflecting the movement of the liquid interface along the length of the sensor head 10. Relatively cheap low frequency electronic components can be used to amplify and process these low frequency signals. Thus the combination of the electrode design shown in FIG. 2A, the electronic scheme shown in FIG. 15 and the algorithm of FIG. 13 will allow for a cheap and straightforward liquid level sensor which is capable of measuring the level of liquids with dielectric constants varying in a significant but limited range.

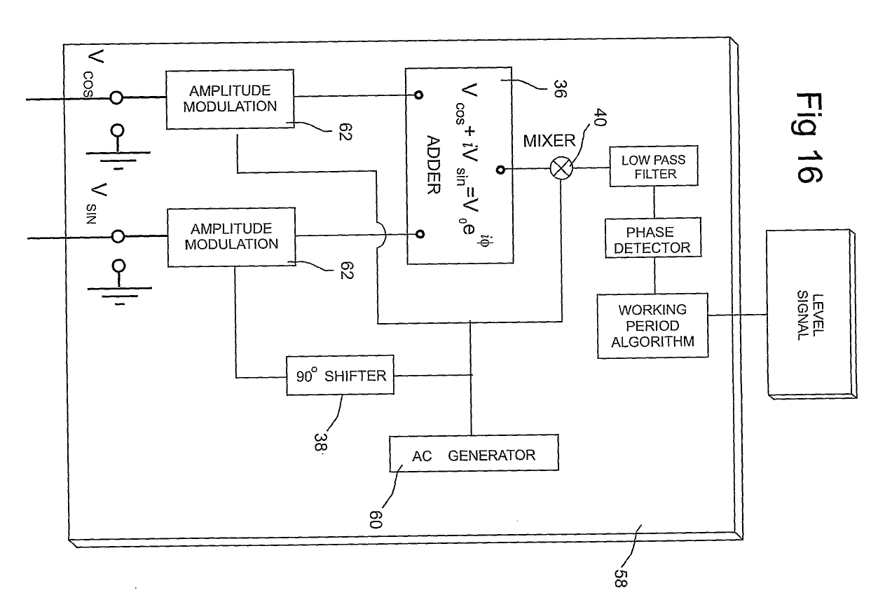

FIG. 16 further shows details of the possible ratiometric algorithm of FIG. 14A or FIG. 15 in which calculation of the arctangent function is done using an analogue electronics approach. This is achieved in a manner similar to the one shown in FIG. 14B. However in the embodiment shown in FIG. 16 the measurements in the cosine-like and sine-like channels are performed so that DC signals are created in the sine-like and cosine-like channels. Such DC signals are slowly varying over time reflecting the actual vibrations and movement of the liquid level along the length of the sensor head 10. The DC voltages in the sine-like and cosine-like measurement channels are than used to provide amplitude modulation for the AC signal from the relatively low frequency AC generator operating at frequency of about 10 kHz or preferably below 100 kHz. Resulting AC signals from the sine-like and cosine-like measurement channels are added in the adder 36 with a 90 degree shift introduced by a shifter 38 for the sine-like channel. The resulting AC signal V=V_{cos}+i*Vₛᵢₙ=V₀e^{iφ} has a phase shift relative to the signal from the AC generator with a value of phase shift φ equal to atan(Vₛᵢₙ/V_{cos}). Thus the value of the phase shift is equal to the phase of the liquid level interface if measured along the period of the electrodes of the sensor head 10. Thus by implementing phase sensitive mixing with the signal from the additional AC generator 60 and measuring the phase of the AC signal after adder 36 it is possible to determine the exact position of the liquid interface inside the unit period of the pattern of FIG. 2A.

FIG. 4A is a schematic representation of a fourth embodiment of a liquid level sensor according to the invention. The sensor head 10 may be made using PCB material by photolithography. A regular array of pixels (electrodes) 12, 14, 16, 18 may be organised along the straight line or along any curved line including a circle. In FIGS. 4A and 4B we show the wiring of the pixels 12, 14, 16, 18, which involves periodic connections to pixels in the array. Generally speaking all the pixels 12, 14, 16, 18 could be wired separately, but the design shown in FIGS. 4A and 4B reduces the number of wires used for connecting the sensor head 10 to the outside electronics 20 and therefore is preferable if the cost of the sensor should be minimised.

The sensor should be able to measure mutual capacitance between all the adjacent pixels 12, 14, 16, 18 in the array in order to identify the point at which permittivity is suddenly changed. For example, such point could correspond to the interface between the liquid and the air in a tank. Results of the measurements of the mutual capacitance may be interpolated in order to locate the point at which permittivity changes. Such interpolations may provide accuracy significantly better than the spacing between adjacent pixels 12, 14, 16, 18. The algorithm for interpolation should not involve an assumption of a very abrupt interface. Ideally the same algorithm should be applicable for measurements of the position of a moving dielectric or metallic target with typical dimensions just smaller than the size of the pixel 12, 14, 16, 18 in the array.

This particular embodiment of the sensor array wiring and signal processing enables the simplest algorithm to interpret the changes of the mutual capacitance in the array of pixels 12, 14, 16, 18.

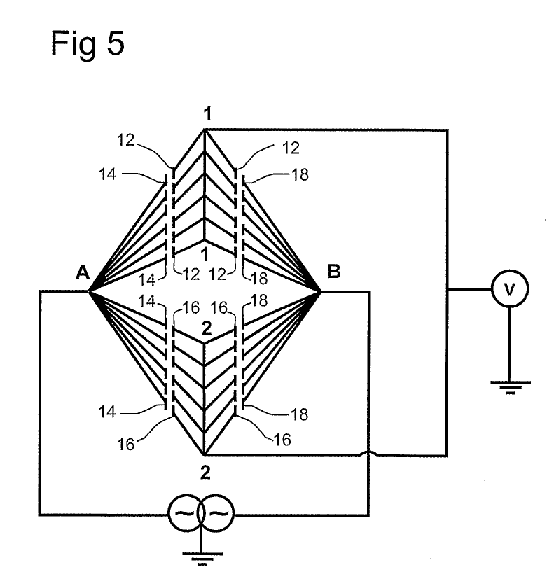

In FIGS. 4A and 4B we show a periodic wiring of the array of pixels 12, 14, 16, 18 which splits all pixels into the periodic groups of four pixels 12, 14, 16, 18. An AC voltage is then applied to one pair of pixels 14, 18 (A-B on FIG. 4A) and the induced AC voltage is then measured on another pair of pixels 12, 16 (1-2 on FIG. 4A). The equivalent electric scheme of the array is shown in FIG. 5 for the case of six periods in the whole array; each period consists of four pixels. It is evident from both FIG. 4A and FIG. 5 that the pixels 12, 14, 16, 18 in the array are configured in the form of a balanced Wheatstone Bridge in which all impedances are equal. As a result an induced voltage V₁₋₂ is very close to zero but only if the permittivity is homogeneous around the sensor head. An abrupt change of the permittivity (for instance at the liquid/air interface) will unbalance the bridge and will induce a finite voltage between the terminals (terminal 1 and terminal 2 in FIG. 5).

The value of the signal of the induced voltage may be used to determine the position of “the centre of gravity” of the inhomogeneity in the permittivity with very good accuracy. Below we consider a very specific embodiment of the algorithm, which enables the simplest way of calculating the exact position of “the centre of gravity” of the inhomogeneity in the permittivity.

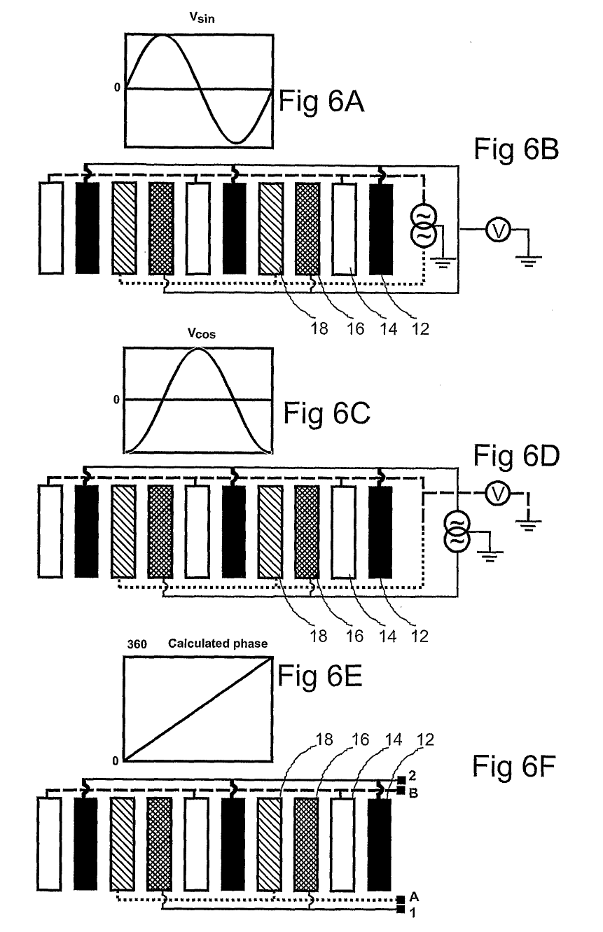

The signal induced in the capacitive bridge will change in a periodical manner according to the position of “the centre of gravity” of the inhomogeneity along the sensor head 10. FIG. 6A shows this dependence in the case when AC voltage is applied to the terminals A-B and AC voltage is induced on the terminals 1-2. The induced signal will be equal to zero once “the centre of gravity” of the inhomogeneity coincides with the centres of the contacts (pixels 14, 18) used for excitation (contacts A and B of FIG. 6B). The induced voltage reaches the maximum value once “the centre of gravity” of the inhomogeneity coincides with the centres of the contacts (pixels 12, 16) used for detection (contacts 1 and 2 of FIG. 6B).

A constant phase shift may be introduced to the dependence shown in the FIG. 6A especially in the case when the width of the pixels (contacts) is significantly smaller than the gap between the contacts. This shift will be caused by second order correction—namely by the mutual capacitance of pixels not immediately adjacent to each other. The exact phase of the shift will be sensitive to a certain extent to the value of the permittivity in the system and to exact details of the inhomogeneity. For instance, in the case of the liquid/air interface this phase shift will vary slightly depending on the value of the permittivity of the liquid. It might be also useful to slightly vary the width of the pixels or the gap between the pixels according to the position of the pixel in the array to compensate for edge effects, which again could be caused by second order effects—namely by the mutual capacitance of pixels not immediately adjacent to each other.

One of the immediate advantages of the wiring scheme shown in FIGS. 4A and 5 is the fact that the mutual capacitance between the adjacent pixels 12, 14, 16, 18 separated by just one pixel does not add much to the phase shift and the edge effects described above. Indeed the mutual capacitance between pixels 14, 18 (A-B) or pixels 12, 16 (1-2) will shunt the useful signal but will not contribute to unbalancing of the bridge scheme. On the contrary a mutual capacitance of the adjacent pixels separated by two pixels will contribute to the edge effect and to the phase shifting effect. But these effects will likely to be pronounced only for liquids with very large permittivities like water as such mutual capacitance (of the adjacent pixels separated by two pixels) might be almost 10 times smaller than the capacitance between immediately adjacent pixels.

One might attempt to make the width of the pixels much bigger if compared to the gap between pixels in order to reduce the amplitude of the constant phase shift. The drawback of this approach is a gradual transformation of the signal from the sinusoidal-like to a meander-like form when the width to gap ratio is continuously increased. The electric field in the array with quite dissimilar width and gap will be localised only around the gaps between pixels. As a result the unbalance of the bridge will occur only when the inhomogeneity region is located near the gaps between the pixels. In the case of a sharp interface between liquid and gas the inhomogeneity region is very abrupt, which rules out the usage of very wide pixels.

The period of the sinusoidal-like signal shown in FIG. 6A is equal to the four unit's (pixels') length. If the excitation-detection pair is swapped in a manner shown in FIG. 6B, the dependence of the signal against the liquid level interface position along the length of the sensor head 10 is shifted in the space by exactly a single unit (pixel) length. In other words, swapping an excitation-detection pair is absolutely equivalent to physically moving the whole pixel array by one unit length. This unique property of the specific wiring of the periodic pixel's array shown in FIG. 4A could be used to detect the position of the “the centre of gravity” of the inhomogeneity with very high precision. Indeed as shown in FIG. 6C the sinusoidal-like signal transforms into a cosinusoidal-like signal once the excitation-detection pair is swapped. This allows the calculation of the phase of “the centre of gravity” of the inhomogeneity inside the four-unit period in the pixel array (see FIG. 6E).

An ability to measure the exact position of “the centre of gravity” of the inhomogeneity as a phase relative to the position inside the four-unit period of the array (see FIG. 6E) allows making measurements, which are not sensitive to the absolute amplitude of the induced sine-like or cosine-like signals. Such ratiometric technique allows stable measurements, which are much less sensitive to the details of the inhomogeneity itself. In the case of measuring the position of the liquid/air interface, this ratiometric approach allows measurements, which are practically insensitive to the exact value of the permittivity of the liquid.

A second order correction caused by the mutual capacitance of the adjacent pixels separated by other two pixels will introduce some phase shift as discussed above. The value of this shift will vary slowly with the permittivity of the liquid and so the value of the permittivity will in fact affect the reading of the sensor. However this induced error will be almost negligible when measuring liquids with sufficiently low and stable values of permittivity.

For example, consider a design for a fuel level meter. The permittivity for fuel is about two. Even some small additives of water (permittivity ˜81) or acetone (permittivity ˜21) could change the dielectric constant of fuel by a significant amount. Moreover, the permittivity of the fuel depends on the octane rating. Assuming that the permittivity of the fuel is defined with an accuracy better than 10%, a typical capacitive level gauge will provide measurements with the same accuracy of about 10% of the full range. A sensor according to the invention will provide much better accuracy. First, by measuring the total impedance of the sensor (see FIG. 5) it is possible to determine the level of the fuel with an accuracy of 10%. This accuracy is mainly determined by the uncertainty of the permittivity of the fuel. This accuracy is enough to determine which period of the sensor array (six periods on the array shown in FIGS. 4A and 5) is currently unbalanced due to the location of the fuel/air interface inside its range. Further measurements of cosine-like and sine-like outputs of the sensor 10 allow calculation of the position of the fuel/air interface with accuracy better than one part per hundreds of the unit size. The variation of the parasitic phase shift (discussed above) with the value of the permittivity will introduce the main error in the measurements with the novel sensor head. But such systematic error will not exceed just a few percent of the unit size and so will contribute less than a fraction of the percent on fall scale.

A particular geometry of the wiring of the periodic array of the capacitive pixels shown in FIG. 4A and 5 has a particular feature. Namely, it is possible to move effectively the whole measurement head by one unit length by just swapping excitation-detection pair. In order to keep the whole bridge set-up balanced in both cases of excitation-detection there is a need for connecting and disconnecting two pixels at the very edges of the array as shown schematically in FIG. 4A.

In the case when the pair A-B is used for excitation, the left switch 22 should be turned on and the right switch 21 should be turned off. When the excitation pair is instead switched to the pair 1-2 it is necessary to switch off the left switch 22 and switch on the right one 21. By performing this switching the whole array effectively moves by one unit length to the right. The existence of two switches 21, 22 at the very edges of the array is a compromise to keep the bridge system balanced. Generally speaking it is possible to keep both switches on during both measurements, measure simultaneously on both channels, and remove the induced degree of unbalance in the software. It is well known how to remove in the software the breakthrough signal caused by the constant unbalance in the ratiometric sine-like and cosine-like measurement channels. However the whole measurement algorithm might be more stable if the initial set-up is well balanced in respect to the homogeneous permittivity distribution around the measurement head.

As the measurement set-up shown in FIG. 6 is based on different commutations of excitation and detection channels, an additional simultaneous commutation of pixels at the very edge of the pixel system doesn't introduce much further complication for the electronics design.

It is not always possible to know with a reasonable accuracy the value of the permittivity of the liquid which will be measured. It is also impossible to determine the active period of the sensor head when using the sensor head for detecting a movement of an arbitrary dielectric or metallic target. In such situations a further geometrical encoding of the pixel system should be performed. A specific design for such further geometrical encoding is shown in FIG. 7. A slit across the diagonal of the sensor array and additional wiring is used to extract more information about the position of the “centre of gravity” of the inhomogeneity along the sensor head 10. By measuring the value of the signal separately on both halves of the previously monolithic pixel it is possible to construct an additional ratiometric value (see FIG. 8) of the type:

$$R = \sqrt{\frac{{( {V}_{12}^{**} - {V}_{12}^{*} )}^{2} + {( {V}_{AB}^{**} - {V}_{AB}^{*} )}^{2}}{{( {V}_{12}^{**} + {V}_{12}^{*} )}^{2} + {( {V}_{AB}^{**} - {V}_{AB}^{*} )}^{2}}}$$

where V* relates to the voltage measurements performed on the top part of the pixels and V** relates to the voltage measurements performed on the bottom parts of the pixels.

Once the rough position of “the centre of gravity” of the inhomogeneity along the sensor head is determined in the manner illustrated by FIG. 8, a more precise position inside a particular period of the pixel array may be determined using a phase approach described in relation to FIG. 6.

Such algorithm for measurements with an array of pixels enables a universal sensor head 10 which may be used to measure a level of unknown liquid in a vessel or the movement of non-predetermined dielectric or metallic target.

A sensor head 10 may be encapsulated by a relatively thick dielectric layer to enable measurements of the level of a conductive liquid in a vessel. This will reduce but not completely eliminate the sensitivity of the measurement set-up to the thin film of conductive liquid, which might shunt pixels. Ideally this dielectric cover layer should be made from hydrophobic materials to discourage the formation of such parasitic conductive film. In this situation the sensor head will work as a pure capacitive bridge in air and as a hybrid capacitive/resistive bridge for pixels immersed into the conductive liquid. As discussed above the complex impedance of the whole sensor head (see FIG. 5) could be roughly calibrated if the liquid properties do not vary too much. This will allow determining the active period of the pixel array and then determining an exact position of the interface by using the phase technique of the type shown in FIG. 6. If the properties of the liquid vary too much with temperature or are effected significantly by additives, a sensor head 10 with a diagonal slit of the type shown in FIG. 7 may be implemented. Again the sensor head 10 should be covered with a thick hydrophobic dielectric layer to reduce problems with residual films of conductive liquid on the surface of the sensor. The sensor head without dielectric cover may be used as a combined capacitive and resistive bridge sensor.

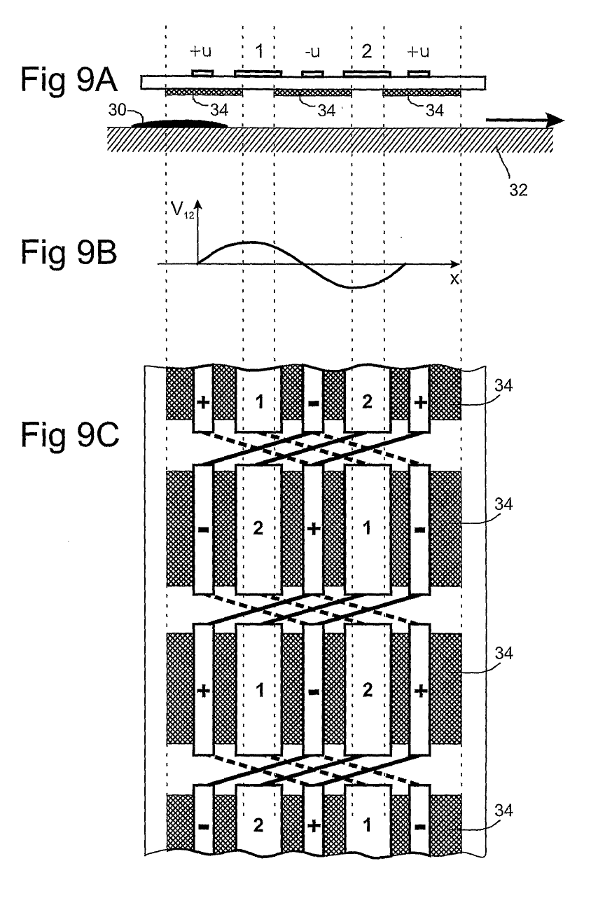

The embodiment shown in FIGS. 9A to 9C comprises a symmetrical balanced capacitive pixel array, which allows the detection of the formation of an inhomogeneity 30 on the surface of a metallic body 32. This inhomogeneity 30 might be in the form of a dielectric or conductive bump with a typical size of about a few millimetres (or more) in diameter and thickness of about 10 microns (or more).

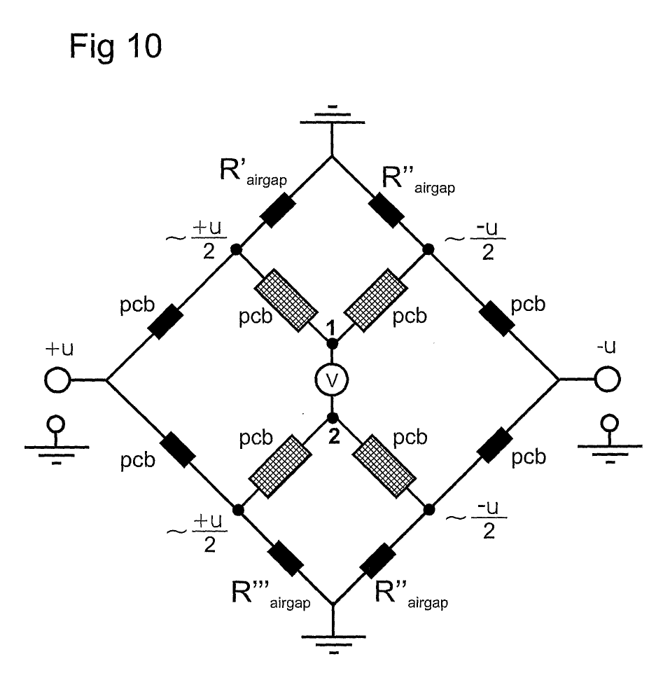

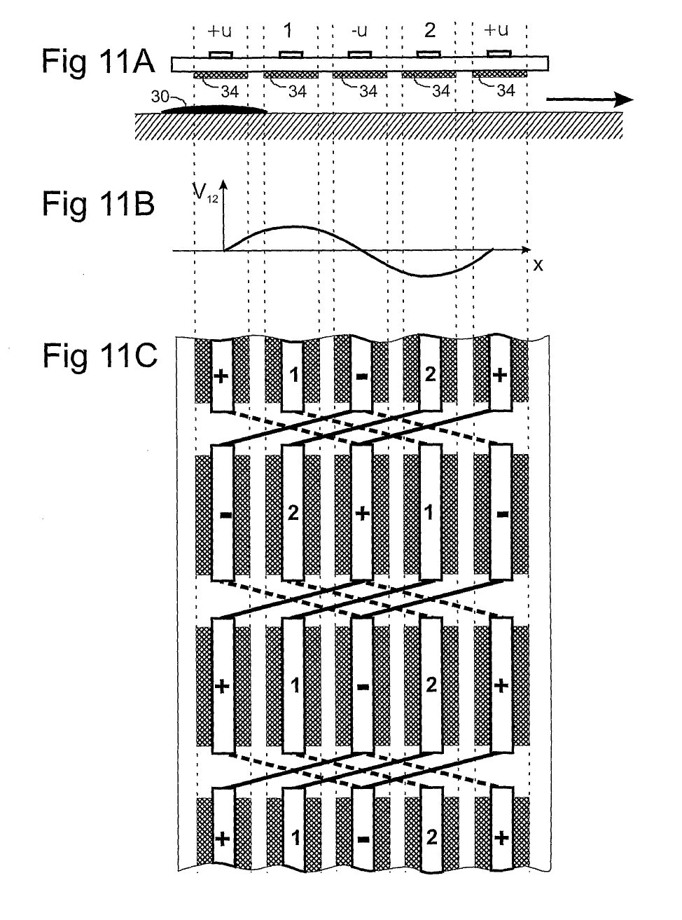

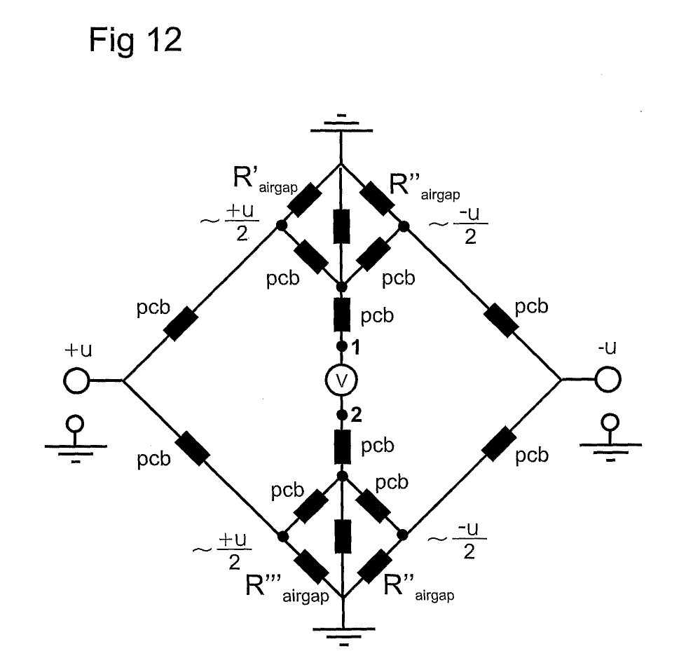

An example of a completely balanced capacitive array is shown in FIG. 9A and another, simpler, version is shown in FIG. 11 A. Due to its geometry, the array is well balanced even if it is tilted slightly away from the position parallel to the metallic surface 32. An equivalent electrical scheme of the array is shown in FIGS. 10 and 12, respectively, in which the same size components indicates impedances of very similar values. The larger size impedance are configured to have larger values. As is apparent from FIG. 10 the capacitance between the voltage probes +u, −u and the corresponding bottom pixel (electrode) 34 should be of the order of the capacitance between this bottom pixel 34 and the metallic surface 32. The voltage measured between terminals 1 and 2 of the balanced bridge array shown in FIG. 10 is maximised by adjusting the values of these capacitances to be of the same order of magnitude.

The capacitance between the measurement wires 1 or 2 and bottom pixels 34 should be smaller than the capacitance between the bottom pixels 34 and the metallic surface 32. By changing geometry like the width of each stripe, gaps between different pixels, etc. it is possible to create a range of values for mutual capacitances and so optimise the value of the signal measured by the balanced bridge. Another less flexible adjustment could be achieved in the case shown in FIGS. 11 and 12.

Perturbation of the gap between the bottom pixels 34 of the array and the metallic surface 32 will cause unbalancing of the bridge and hence some signal will appear between the terminals 1 and 2. By measuring the amplitude of this signal information about the moving inhomogeneity may be obtained.

In the case of measuring a small amount of material stuck to the surface of a metallic roller, a synchronous detection system might be employed in order to obtain a better signal to noise ratio and to discriminate for a useful signal. In such a case, only the positive or the negative amplitude of the response may be measured. The amplitude of the synchronously detected signal will be dependent on the mass of the object (thickness and size) that is stuck to the surface of the roller.

This design for a balanced capacitive array could be used for earlier detection of problems related to sticking of some conductive or non-conductive materials to the surface of the metallic roller.

In summary, a capacitive position sensor has a periodic array of electrodes which form capacitors between pairs of the electrodes. The location of a dielectric inhomogeneity in the vicinity of the sensor is determined by comparison of the relative change in the capacitance of the capacitors. The comparison may be carried out using a capacitive Wheatstone Bridge arrangement. The sensor configuration has the advantage that it is independent of the absolute value of the dielectric constant of the environment in which the sensor is located.

1.-21. (canceled)

22. A capacitive position sensor comprising:
a plurality of electrodes spaced along a measurement path;
excitation circuitry operable to generate and to apply first and second excitation signals to first and second sub-sets of said electrodes respectively;
detection circuitry coupled to third and fourth sub-sets of said electrodes and operable:
i) to obtain a first detection signal that varies with the mutual capacitance between the electrodes in the first and second sub-sets and the electrode or electrodes in the third sub-set;
ii) to obtain a second detection signal that varies with the mutual capacitance between the electrodes in the first and second sub-sets and the electrode or electrodes in the fourth sub-set;
iii) to determine a ratio of the first and second detection signals, which ratio varies with the position along said measurement path of an inhomogeneity which affects the mutual capacitance between electrodes in the vicinity of the inhomogeneity; and
iv) to determine the position of said inhomogeneity along said measurement path using said determined ratio; and
wherein at least two of said sub-sets of electrodes each comprises a plurality of electrodes which are spaced apart along said measurement path and interleaved between the electrodes of the other one of said at least two sub-sets.

23. A sensor according to claim 22, wherein said detection circuitry is operable: v) to receive first and second receive signals from said third sub-set of said electrodes and third and fourth receive signals from said fourth sub-set of said electrodes; vi) to obtain said first detection signal by combining said first and second receive signals; and vii) to obtain said second detection signal by combining said third and fourth receive signals.

24. A sensor according to claim 23, wherein said detection circuitry is operable: vi) to obtain said first detection signal by subtracting said first and second receive signals; and vii) to obtain said second detection signal by subtracting said third and fourth receive signals.

25. A sensor according to claim 23, wherein said third sub-set of said electrodes comprises a plurality of curved electrodes arranged in succession along the measurement path and from which said first receive signal is received by said detection circuitry and wherein said fourth sub-set of said electrodes comprises a corresponding plurality of curved electrodes arranged in succession along the measurement path and from which said second receive signal is received by said detection circuitry.

26. A sensor according to claim 25, wherein adjacent electrodes of said third sub-set are positioned adjacent opposite ones of said first and second sub-sets of said electrodes and wherein adjacent electrodes of said fourth sub-set are positioned adjacent opposite ones of said first and second sub-sets of said electrodes.

27. A sensor according to claim 25, wherein said plurality of curved electrodes of said third sub-set are arranged in a periodic array along the measurement path and wherein said plurality of curved electrodes of said fourth sub-set are shifted along said measurement path relative to the electrodes of said fourth sub-set by a non-zero offset less than one half said period.

28. A sensor according to claim 22, wherein said first sub-set of said electrodes comprises a first drive electrode which extends over a measurement range of the sensor and to which said first excitation signal is applied and wherein said second sub-set of said electrodes comprises a second drive electrode which is spaced apart from said first drive electrode, which extends over the measurement range of the sensor and to which said second excitation signal is applied.

29. A sensor according to claim 22, wherein said third sub-set of said electrodes comprises a first detection electrode which extends over a measurement range of the sensor and from which said first detection signal is obtained by said detection circuitry and wherein said fourth sub-set of said electrodes comprises a second detection electrode which is spaced apart from said first detection electrode, which extends over a measurement range of the sensor and from which said second detection signal is obtained by said detection circuitry.

30. A sensor according to claim 22, wherein said first sub-set of said electrodes comprises a plurality of curved electrodes arranged in succession along the measurement path over a measurement range of the sensor and to which said first excitation signal is applied and wherein said second sub-set of said electrodes comprises a corresponding plurality of curved electrodes arranged in succession along the measurement path over the measurement range of the sensor and to which said second excitation signal is applied.

31. A sensor according to claim 30, wherein said plurality of curved electrodes of said first sub-set are arranged in a periodic array along the measurement path and wherein said plurality of curved electrodes of said second sub-set are shifted along said measurement path relative to the electrodes of said fourth sub-set by a non-zero offset less than one half said period.

32. A sensor according to claim 22, wherein said electrodes are connected in a bridge arrangement that is substantially electrically balanced such that in the absence of an inhomogeneity in the vicinity of the sensor substantially no detection signals are obtained from said third and fourth sub-sets of electrodes.

33. A sensor according to claim 22, wherein said first and second sub-sets of electrodes are spaced apart from each other along the measurement path and wherein said third and fourth sub-sets of electrodes are positioned between said first and second sub-sets of said electrodes.

34. A sensor according to claim 22, wherein said third and fourth sub-sets of electrodes are spaced apart from each other along the measurement path and wherein said first and second sub-sets of electrodes are positioned between said first and second sub-sets of said electrodes.

35. A sensor according to claim 34, wherein said first and second detection signals vary with said position in an approximate sinusoidal manner and wherein said detection circuitry is operable to determine said position by calculating a ratiometric arctangent function of said first and second detection signals.

36. A sensor according to claim 36, wherein said detection circuit is operable to combine said first and second detection signals to generate a combined signal whose phase varies with the value of said ratiometric arctangent function and wherein said detection circuitry is operable to determine the value of said ratiometric arctangent function by determining the phase of said combined signal.

37. A sensor according to claim 22, wherein each of said third and fourth sub-sets of electrodes comprises first and second groups of electrodes, each group of electrodes comprising a periodic array of electrodes, wherein the electrodes of said first and second groups of the same sub-set are shifted along said measurement path relative to each other by half said period and wherein the electrodes of said third sub-set are shifted along said measurement path relative to the electrodes of said fourth sub-set by a non-zero offset less than one half said period.

38. A sensor according to claim 37, wherein the electrodes of said third sub-set are shifted along said measurement path relative to the electrodes of said fourth sub-set by a quarter of said period.

39. A sensor according to claim 22, wherein said first and second excitation signals are approximately 180 degrees out of phase with each other.

40. A sensor according to claim 22, wherein said excitation circuit is operable to generate said second excitation signal by inverting said first excitation signal.

41. A sensor according to claim 22, wherein said excitation circuit is operable to generate excitation signals that cyclically vary with time.

42. A sensor according to claim 41, wherein said excitation circuit is operable to generate AC excitation signals.

43. A sensor according to claim 41, wherein said excitation circuit is operable to generate excitation signals that comprise sequences of voltage pulses.

44. A sensor according to claim 22, wherein said electrodes are formed from conductive tracks on a printed circuit board.

45. A sensor according to claim 22, wherein said electrodes are formed by printing conductive material onto a substrate.
